(19) United States
(12) Patent Application Publication
(10) Pub. No.: US 2024/0137026 A1
(43) Pub. Date: Apr. 25, 2024

(54) Techniques For Storing States Of Signals In Configurable Storage Circuits

(71) Applicant: Altera Corporation, San Jose, CA (US)

(72) Inventors: Bee Yee Ng, Bayan Lepas (MY); Ilya Ganusov, San Jose, CA (US); Jun Pin Tan, Kepong (MY)

(73) Assignee: Altera Corporation, San Jose, CA (US)

(21) Appl. No.: 18/397,673

(22) Filed: Dec. 27, 2023

(51) Int. Cl. H03K 19/17728; G01R 31/3185

(52) U.S. Cl. CPC H03K 19/17728; G01R 31/318586

(57) ABSTRACT

An integrated circuit includes a logic circuit block that includes a first adaptive logic module configurable to store a first state of a first signal received from a device-under-test in a first register, a second adaptive logic module configurable to store a second state of a second signal in a second register during a user mode of the integrated circuit simultaneously with the first state of the first signal being stored in the first register, and a third adaptive logic module configurable to store a third state of the first signal in a third register. The first and the third states of the first signal are stored for consecutive clock cycles in the first register and the third register. The logic circuit block is configurable to scan out the second state in the second register and the third state in the third register.

### TECHNICAL FIELD

The present disclosure relates to electronic integrated circuits, and more particularly to techniques for storing states of signals in configurable storage circuits.

### BACKGROUND

Configurable integrated circuits (ICs) can be configured by users to implement desired custom logic functions. In a typical scenario, a logic designer uses computer-aided design (CAD) tools to design a custom circuit design. When the design process is complete, the computer-aided design tools generate configuration data. The configuration data is then loaded into configuration memory elements that configure configurable logic circuits in the integrated circuit to perform the functions of the custom circuit design.

### BRIEF DESCRIPTION OF DRAWINGS

FIG. 1 is a diagram that illustrates a configurable logic circuit block having adaptive logic modules.

FIG. 2A is a diagram that illustrates an adaptive logic module that is an example of circuits in the configurable logic circuit block of FIG. 1.

FIG. 2B is a diagram that illustrates two NOR logic gate circuits that generate a multiplexer select signal that configures one of the multiplexers of FIG. 1.

FIG. 2C is a diagram that illustrates two additional NOR logic gate circuits that generate another multiplexer select signal that configures another multiplexer of FIG. 1.

FIG. 2D is a diagram that illustrates an example of additional circuitry that can be included in an adaptive logic module, according to an example.

FIG. 3 is a diagram that illustrates a portion of an integrated circuit that includes several configurable logic circuit blocks.

FIG. 4 is a diagram that illustrates a portion of another integrated circuit that includes several configurable logic circuit blocks.

FIG. 5 illustrates an example of a configurable logic integrated circuit (IC) that can include the circuitry disclosed herein with respect to any of FIGS. 1, 2A-2C, 3, and/or 4.

FIG. 6A illustrates a block diagram of a system that can be used to implement a circuit design to be programmed onto a programmable logic device using design software.

FIG. 6B is a diagram that depicts an example of a programmable logic device that includes three fabric die and two base die that are connected to one another via microbumps.

FIG. 7 is a block diagram illustrating a computing system configured to implement one or more aspects of the embodiments disclosed herein.

### DETAILED DESCRIPTION

Developers of integrated circuits typically need to verify that a gate-level representation of a circuit design for an integrated circuit behaves as defined in the design specification before manufacturing the integrated circuit. The goal is to locate and fix errors in the gate-level representation of the circuit design early such that expensive re-spins can be avoided or at least kept to a minimum. Gate-level timing simulation has traditionally been used to perform this verification step. Gate-level timing simulation uses a test bench together with a software model of the circuit design to generate output responses to different input vectors. The test bench then compares these output responses with expected results. However, the execution time of gate-level timing simulation often exceeds any practical durations, especially for very large circuit designs that can include billions of gates.

Hardware emulation of circuit designs has emerged as a faster, more practical alternative to simulation. Configurable integrated circuits are often used as a platform for performing hardware emulation of circuit designs. After a circuit design is compiled and implemented in one or more configurable integrated circuits, a test bench can be executed on the configured integrated circuits to generate output responses to different input vectors. The test bench can then compare these output responses with expected results. The configured integrated circuits can be used in real-world operating conditions with corresponding stimuli. Verifying the gate-level representation of a circuit design using hardware emulation reduces execution time by several orders of magnitude compared to gate-level timing simulations.

For debugging purposes (e.g., to localize the source of an error), the execution of the test bench on the configured integrated circuits can be interrupted. Then, a readback operation can be performed to extract the states of the synchronous circuits in the configured integrated circuits (i.e., the values stored in storage circuits such as registers, latches, memories, etc.) through debug ports, such as the Internal Configuration Access Port (ICAP) or the Joint Test Action Group (JTAG) ports for further analysis.

The values that are stored in the synchronous circuits can be accessible using scan storage circuits coupled in one or more scan chains. These scan storage circuits are also referred to as shadow storage circuits. For debugging purposes, it may be desirable that the readback operation can extract the state of every synchronous circuit of the circuit design. A writeback operation can be performed to write data to synchronous circuits in the circuit design during debugging. Some integrated circuits use scan chains to shift data for non-destructive register readback (RB) and writeback (WB) operations from synchronous circuits.

In some types of configurable integrated circuits, RB data can be transferred between the scan chain and the core logic circuitry of the integrated circuit through a data register and a local sector manager (LSM). The RB data transmitted through the scan chain, the data register, and the LSM to the core logic circuitry may have a long latency, for example, because the RB data may have to be transmitted at a low frequency through thousands of synchronous circuits. The RB and WB data is transmitted through the full scan chain, including through synchronous circuits that are not used in the circuit design, adding to the latency. This technique incurs significant dynamic power overhead, because 50% of all synchronous circuits in the integrated circuit are toggled during RB and WB, including any unused synchronous circuits.

According to some examples disclosed herein, an integrated circuit includes first and second configurable storage circuits that are coupled in a scan chain. The integrated circuit is configured according to a circuit design for a design-under-test (DUT) during an emulation mode. The circuit design includes synchronous circuits. The first configurable storage circuit is configurable to store the state of one of the synchronous circuits in the circuit design to perform a non-destructive register readback (RB) operation. The second configurable storage circuit is configurable to store an output of the first configurable storage circuit that represents the state of the synchronous circuit during the non-destructive register RB operation.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the term “connected” means a direct electrical connection between the circuits that are connected, without any intermediary devices. The term “coupled” means either a direct electrical connection between circuits or an indirect electrical connection through one or more passive or active intermediary devices that allows the transfer of information between circuits. The term “circuit” may mean one or more passive and/or active electrical components that are arranged to cooperate with one another to provide a desired function.

This disclosure discusses integrated circuit devices, including configurable (programmable) logic integrated circuits, such as field programmable gate arrays (FPGAs). As discussed herein, an integrated circuit (IC) can include hard logic and/or soft logic. The circuits in an integrated circuit device (e.g., in a configurable logic IC) that are configurable by an end user are referred to as “soft logic.” “Hard logic” generally refers to circuits in an integrated circuit device that have substantially less configurable features than soft logic or no configurable features.

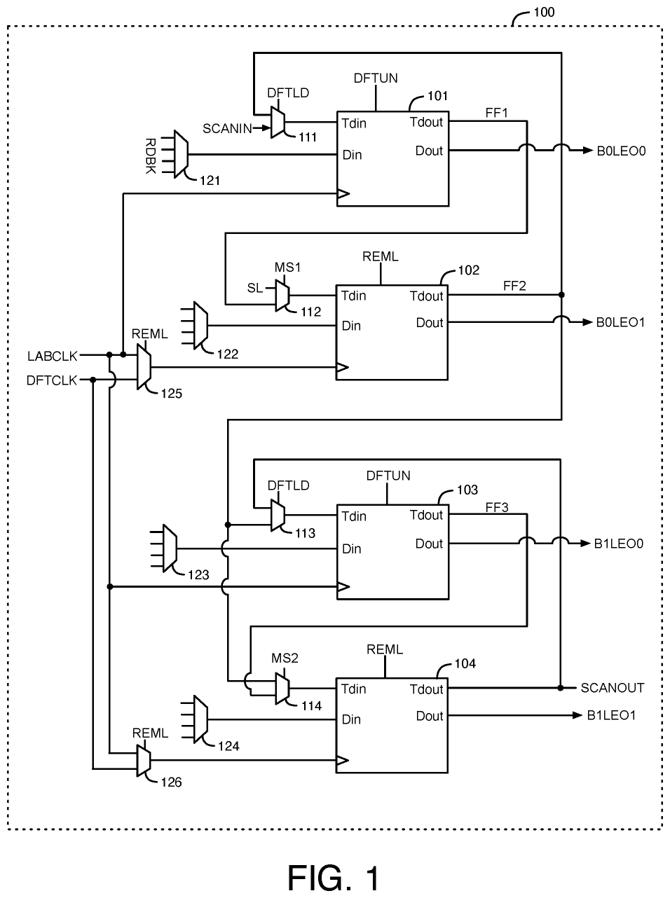

FIG. 1 is a diagram that illustrates a configurable logic circuit block 100 having adaptive logic modules. Configurable logic circuit block 100 can be in any type of integrated circuit (IC), such as, a configurable (i.e., programmable) logic IC, a microprocessor IC, or a graphics processing unit (GPU) IC. The IC typically includes other circuitry not shown in Figure (FIG. 1, such as, memory circuits, digital signal processing circuits, additional configurable logic circuits, additional scan chains, input/output circuits, etc.

Configurable logic circuit block 100 includes 4 adaptive logic modules 101-104 and 10 multiplexer circuits 111-114 and 121-126. The outputs of the multiplexer circuits 121-124 are coupled to the data inputs Din of adaptive logic modules 101-104, respectively. The outputs of multiplexer circuits 111-114 are coupled to the test data inputs Tdin of adaptive logic modules 101-104, respectively. The test data output Tdout of adaptive logic module 101 is coupled to a second data input of multiplexer circuit 112. The test data output Tdout of adaptive logic module 102 is coupled to the first data input of multiplexer circuit 111, to the second data input of multiplexer circuit 113, and to the first data input of multiplexer circuit 114. The test data output Tdout of adaptive logic module 104 is coupled to the first data input of multiplexer circuit 113.

A first clock signal LABCLK is provided to the clock inputs of adaptive logic modules 101 and 103. The first clock signal LABCLK and a second clock signal DFTCLK are provided to data inputs of multiplexer circuits 125-126. The output of multiplexer circuit 125 is coupled to the clock input of configurable adaptive logic module 102. The output of multiplexer circuit 126 is coupled to the clock input of configurable adaptive logic module 104. Multiplexer circuits 125-126 are configured by an emulation control signal REM L.

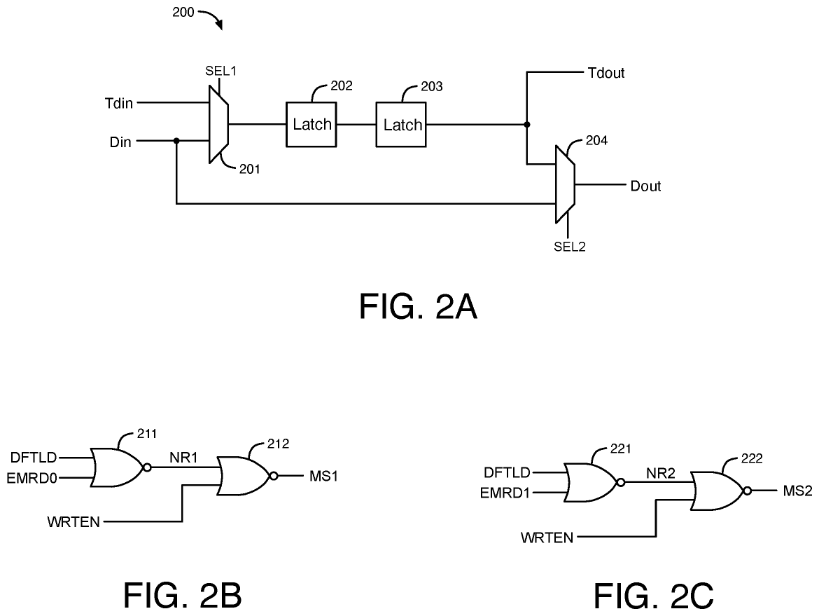

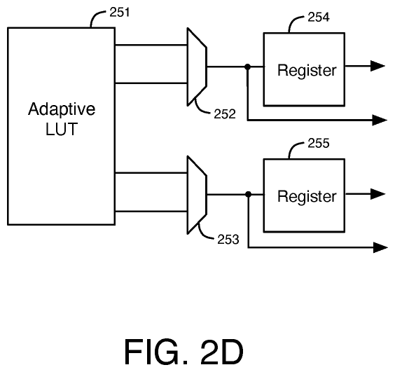

FIG. 2A is a diagram that illustrates an adaptive logic module 200 that is an example of each of the adaptive logic modules 101-104 in configurable logic circuit block 100 of FIG. 1. The configurable adaptive logic module 200 of FIG. 2 includes 2 multiplexer circuits 201 and 204, a primary latch circuit 202, and a secondary latch circuit 203. The input signals at the test data input Tdin and the data input Din of configurable adaptive logic module 200 are provided to the data inputs of multiplexer circuit 201. Multiplexer circuit 201 is configurable by select signal SEL1 to provide the state of one of the input signals at the Tdin or Din inputs to an input of latch circuit 202. Latch circuit 202 stores the state of the signal at its input (as received from multiplexer circuit 201) at the input of latch circuit 203 in response to the clock signal (e.g., LABCLK or DFTCLK) received at the clock input. Latch circuit 203 stores the state of the signal at its input (as received from the output of latch circuit 202) as an output signal at the test data output Tdout and at a first data input of multiplexer circuit 204 in response to the clock signal received at the clock input. Multiplexer circuit 204 is configurable by select signal SEL2 to provide the state of the signal at either the Tdout output or the Din input (at a second data input of multiplexer 204) to the data output Dout of adaptive logic module 200.

Referring again to FIG. 1, multiplexer circuits 111 and 113 are configured by design-for-test (DFT) load control signal DFTLD. Multiplexer circuit 112 is configured by a multiplexer select signal MS1. Multiplexer circuit 114 is configured by a multiplexer select signal MS2.

FIG. 2B is a diagram that illustrates two NOR logic gate circuits 211-212 that generate the multiplexer select signal MS1 that configures multiplexer 112. Control signal DFTLD and a first emulation read control signal EMRD0 are provided to inputs of NOR logic gate circuit 211. NOR logic gate circuit 211 performs a NOR Boolean logic function on signals DFTLD and EMRD0 to generate its output signal NR1. The output signal NR1 of NOR logic gate circuit 211 and an emulation writeback enable signal WRTEN are provided to inputs of NOR logic gate circuit 212. NOR logic gate circuit 212 generates the multiplexer select signal MS1 at its output by performing a NOR logic Boolean function on signal WRTEN and the output signal NR1 of NOR logic gate circuit 211.

FIG. 2C is a diagram that illustrates two additional NOR logic gate circuits 221-222 that generate the multiplexer select signal MS2 that configures multiplexer 114. Control signal DFTLD and a second emulation read control signal EMRD1 are provided to inputs of NOR logic gate circuit 221. NOR logic gate circuit 221 performs a NOR logic Boolean function on signals DFTLD and EMRD1 to generate its output signal NR2. The output signal NR2 of NOR logic gate circuit 221 and emulation writeback enable signal WRTEN are provided to inputs of NOR logic gate circuit 222. NOR logic gate circuit 222 generates the multiplexer select signal MS2 at its output by performing a NOR logic Boolean function on signal WRTEN and the output signal NR2 of NOR logic gate circuit 221.

As discussed above, a configurable integrated circuit can be configured to perform hardware emulation of a circuit design that is operated as a design-under-test (DUT) (also referred to as a device-under-test) during an emulation mode. In the emulation mode, a readback operation can be performed to extract the states of signals stored in synchronous circuits within the circuit design for the configurable integrated circuit that is operated as a DUT. The configurable logic circuit block 100 of FIG. 1 can be configured to implement a non-destructive readback operation with continuous sampling and/or tracing of the states of signals stored in synchronous circuits in a circuit design operated as a DUT during an emulation mode, as disclosed in further detail below.

During the emulation mode, multiplexer circuit 121 is configured to provide the state of one of a set of readback signals RDBK from a synchronous circuit in a circuit design for a design-under-test (DUT) in the IC to the data input Din of the adaptive logic module 101. During a non-destructive readback operation in the emulation mode, signals EMRD0 and WRTEN are set to logic states that cause NOR logic gate circuits 211-212 to set multiplexer select signal MS1 to a logic state that causes multiplexer circuit 112 to provide the signal FF1 at the Tdout output of adaptive logic module 101 to the Tdin input of adaptive logic module 102. In addition, during the non-destructive readback operation in the emulation mode, signals EMRD1 and WRTEN are set to logic states that cause NOR logic gate circuits 221-222 to set multiplexer select signal MS2 to a logic state that causes multiplexer circuit 114 to provide the signal FF2 at the Tdout output of adaptive logic module 102 to the Tdin input of adaptive logic module 104.

During the non-destructive readback operation in the emulation mode, the DFTUN signal is set to a logic state that causes adaptive logic modules 101 and 103 to simultaneously store the states of the signals received from multiplexers 121 and 123 at their data inputs Din in registers and provide these stored states to their test data outputs Tdout as signals FF1 and FF3, respectively. Signal DFTUN can be provided to the select input of multiplexer 201 as signal SEL1 in each of the adaptive logic modules 101 and 103 to cause the signal at the Din input to be provided to the Tdout output through multiplexer 201 and latches 202-203.

Also, during the non-destructive readback operation in the emulation mode, the REML signal is set to a logic state that causes adaptive logic modules 102 and 104 to provide the states of the signals received from multiplexers 112 and 114 at their test data inputs Tdin to their test data outputs Tdout as signals FF2 and SCANOUT, respectively. Signal REML (or a signal derived from REML) can be provided to the select input of multiplexer 201 as signal SEL1 in each of the adaptive logic modules 102 and 104 to cause the signal at the Tdin input to be provided to the Tdout output through multiplexer 201 and latches 202-203.

In addition, multiplexer circuits 125 and 126 are configured by emulation control signal REML to provide the LABCLK clock signal to the clock inputs of the adaptive logic modules 102 and 104. The LABCLK clock signal is provided to the clock inputs of the latches 202-203 in adaptive logic modules 102 and 104. The LABCLK clock signal is also provided to the clock inputs of the latches 202-203 in adaptive logic modules 101 and 103. The DFTLD signal is set to a logic state that causes multiplexer circuits 111 and 113 to provide the states of signals FF2 and SCANOUT, respectively, to their outputs during writeback operation in the emulation mode.

During the non-destructive readback operation in the emulation mode, multiplexer circuit 121 provides the state of one of the readback signals RDBK from a synchronous circuit in the circuit design for the DUT to the data input Din of the adaptive logic module 101. The adaptive logic module 101 then stores the state of the readback signal RDBK selected by multiplexer circuit 121 in a register (e.g., latches 202-203) in adaptive logic module 101 at its Tdout output as signal FF1 in response to clock signal LABCLK. Adaptive logic module 101 functions as a trace register during the non-destructive readback operation.

Multiplexer circuit 112 then provides the state of signal FF1 to the test data input Tdin of adaptive logic module 102. The adaptive logic module 102 then stores the state of signal FF1 in a register (e.g., latches 202-203) in adaptive logic module 102 at its test data output Tdout as signal FF2 in response to clock signal LABCLK. One clock cycle before the adaptive logic module 102 stores a current state of the signal FF1, adaptive logic module 101 stores the current state of the readback signal RDBK selected by multiplexer 121 as the next state of signal FF1. Thus, the current state of the selected readback signal RDBK and the current state of signal FF1 are stored for consecutive cycles of clock signal LABCLK in the register in adaptive logic module 101 and in the register in adaptive logic module 102, respectively. Adaptive logic module 102 functions as a first memory cell for storing each state of the readback signal RDBK selected by multiplexer circuit 121 and stored in adaptive logic module 101 (e.g., in each cycle of clock signal LABCLK).

Multiplexer circuit 114 then provides the state of signal FF2 to the test data input Tdin of adaptive logic module 104. The adaptive logic module 104 then stores the state of signal FF2 in a register (e.g., latches 202-203) in adaptive logic module 104 at its test data output Tdout as signal SCANOUT in response to clock signal LABCLK. The adaptive logic module 102 stores the current state of signal FF1 as the next state of signal FF2 and the adaptive logic module 104 stores a current state of the signal FF2 in two consecutive cycles of clock signal LABCLK. Adaptive logic module 104 functions as a second memory cell for storing each state of the readback signal RDBK selected by multiplexer circuit 121 and stored in adaptive logic module 101. Thus, during the readback operation, the adaptive logic modules 101, 102, and 104 are coupled as a scan chain to store and sequentially shift the states of the readback signal RDBK selected by multiplexer circuit 121.

The adaptive logic module 103 can be configured during a user mode of the integrated circuit to store the state of a signal selected by multiplexer circuit 123 and received at its data input Din. The adaptive logic module 103 is configurable to store the state of the signal received through multiplexer circuit 123 in a register during the user mode simultaneously with the state of the signal being received through multiplexer circuit 121 being stored in the register in adaptative logic module 101. The adaptive logic modules 101-104 can be configured in other modes to provide signals B0LEO0, B0LEO1, B1LEO0, and B1LEO1, respectively, at their data outputs Dout.

FIG. 2D is a diagram that illustrates an example of additional circuitry that can be included in an adaptive logic module, according to an example. The adaptive logic module of FIG. 2D includes an adaptive lookup table (LUT) 251 that generates 4 output signals. The four output signals of LUT 251 are provided to inputs of multiplexer circuits 252-253 as shown in FIG. 2D. The output signals selected by multiplexer circuits 252-253 are provided to registers 254-255, respectively, and also directly to outputs of the adaptive logic module.

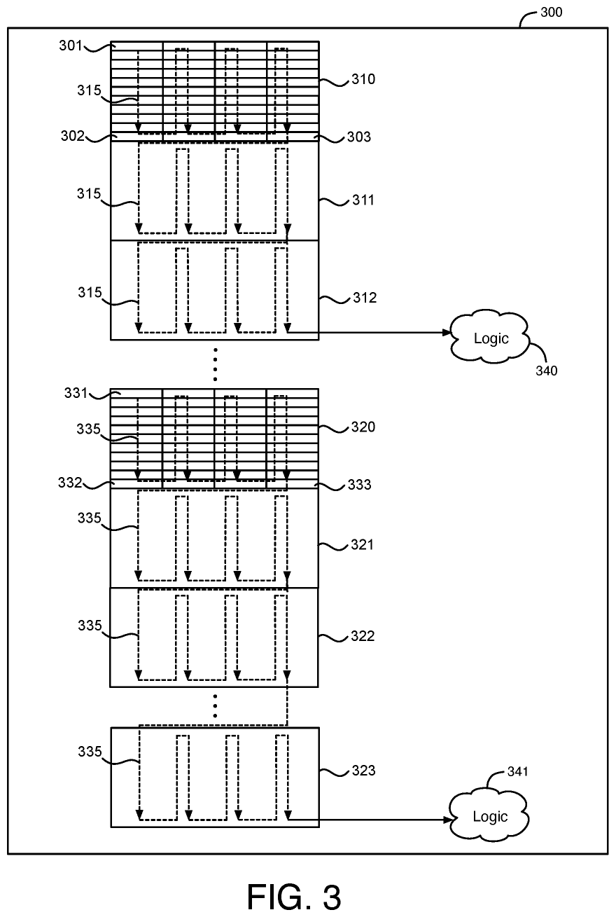

FIG. 3 is a diagram that illustrates a portion of an integrated circuit 300 that includes several configurable logic circuit blocks. Integrated circuit (IC) 300 can be any type of integrated circuit (IC), such as, a configurable (i.e., programmable) logic IC, a microprocessor IC, or a graphics processing unit (GPU) IC. IC 300 includes configurable logic circuit blocks arranged in horizontal rows and vertical columns. Each of the configurable logic circuit blocks in IC 300 is depicted as a rectangle in FIG. 3.

In the example of FIG. 3, the configurable logic circuit blocks are arranged in 4-column logic array blocks (LAB4s), such as LAB4s 310, 311, 312, 320, 321, 322, and 323. FIG. 3 shows a single column of the LAB4s. Each of the 4-column logic array blocks (LAB4s) in the example of FIG. 3 includes 40 configurable logic circuit blocks arranged in 4 columns and 10 rows. As an example, LAB4 310 has 40 configurable logic circuit blocks, including configurable logic circuit blocks 301, 302, and 303. As another example, LAB4 320 has 40 configurable logic circuit blocks, including configurable logic circuit blocks 331, 332, and 333.

In the example of FIG. 3, each of the configurable logic circuit blocks in the LAB4s includes the circuits and conductors (wires) of configurable logic circuit block 100 that are coupled as disclosed herein with respect to FIG. 1. Thus, each of the configurable logic circuit blocks of FIG. 3 includes an instance of configurable logic circuit block 100 of FIG. 1. Each of the configurable logic circuit blocks 301 and 331 of FIG. 3 is configured as described above with respect to FIGS. 1 and 2A-2C. Thus, the adaptive logic module 101 in each of the configurable logic circuit blocks 301 and 331 functions as a trace register during a non-destructive readback operation from a synchronous circuit in a circuit design operating as a DUT during an emulation mode.

During the non-destructive readback operation, the states of a first readback signal from a first synchronous circuit in the circuit design for the DUT are sequentially stored in the adaptive logic module 101 in configurable logic circuit block 301. The configurable logic circuit blocks in LAB4s 310-312 are configured to form a scan chain as shown by the dotted path 315 to sequentially store the states of the first readback signal as received from the adaptive logic module 101 in configurable logic circuit block 301. Thus, in this example, 240 adaptive logic modules 102 and 104 are coupled as memory cells to form a long scan chain for storing 240 sequentially received states of the first readback signal. The configurable logic circuit blocks in the scan chain are coupled together through conductors along path 315.

For example, the multiplexer circuit 112 in each of the remaining configurable logic circuit blocks in LAB4s 310-312 is configured to provide the SCANOUT signal (received as signal SL) from a previous configurable logic circuit block in the scan chain to the Tdin input of the adaptive logic module 102. In this example, each of the configurable logic circuit blocks in LAB4s 310-312 sequentially stores states of the first readback signal in its respective adaptive logic modules 102 and 104, as described above with respect to FIGS. 1 and 2A-2C. Using this configuration, serially received states of the first readback signal are scanned through the scan chain formed by the adaptive logic modules 102 and 104 in the configurable logic circuit blocks in LAB4s 310-312, as shown by the dotted path 315, to logic circuitry 340 (e.g., configurable logic circuitry in a fabric region of a configurable logic IC).

Also, during the non-destructive readback operation, the states of a second readback signal from a second synchronous circuit in the circuit design for the DUT are sequentially stored in the adaptive logic module 101 in configurable logic circuit block 331. The configurable logic circuit blocks in LAB4s 320-323 (and additional LAB4s not shown in FIG. 3) are configured to form a scan chain as shown by the dotted path 335 to sequentially store the states of the second readback signal as received from the configurable logic circuit block 331. The adaptive logic modules 102 and 104 in LAB4s 320-323 etc. are coupled as memory cells to form a long scan chain for storing several serially received states of the second readback signal. The configurable logic circuit blocks in the scan chain are coupled together through conductors along path 335.

For example, the multiplexer circuit 112 in each of the remaining configurable logic circuit blocks in LAB4s 320-323 etc. is configured to provide the SCANOUT signal (received as signal SL) from a previous configurable logic circuit block in the scan chain to the Tdin input of adaptive logic module 102. In this example, each of the configurable logic circuit blocks in LAB4s 320-323 etc. sequentially stores states of the second readback signal in its respective adaptive logic modules 102 and 104, as described above with respect to FIGS. 1 and 2A-2C. Using this configuration, serially received states of the second readback signal are scanned through the scan chain formed by the adaptive logic modules 102 and 104 in the configurable logic circuit blocks in LAB4s 320-323 etc., as shown by the dotted path 335, to logic circuitry 341 (e.g., configurable logic circuitry in a fabric region of a configurable logic IC).

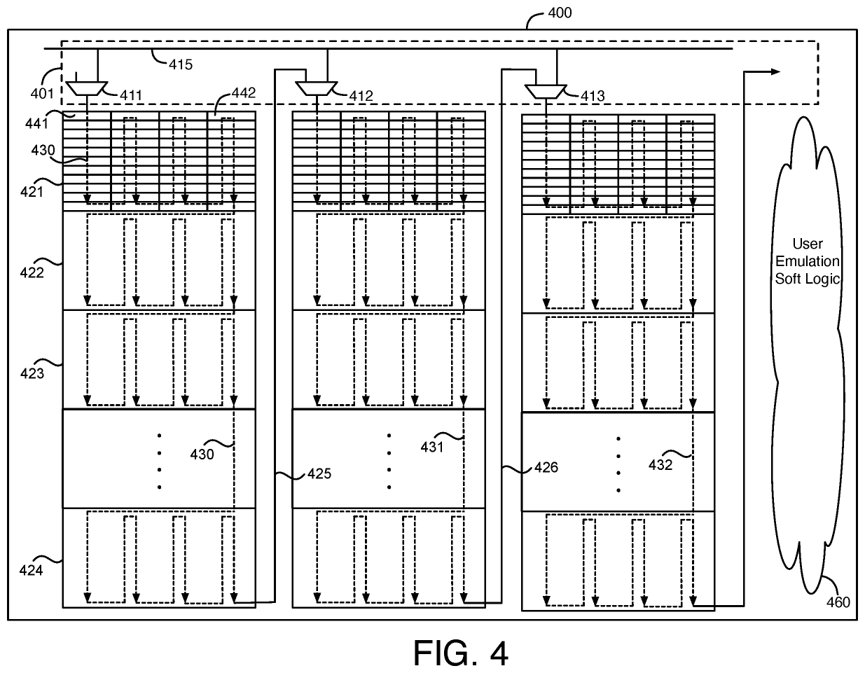

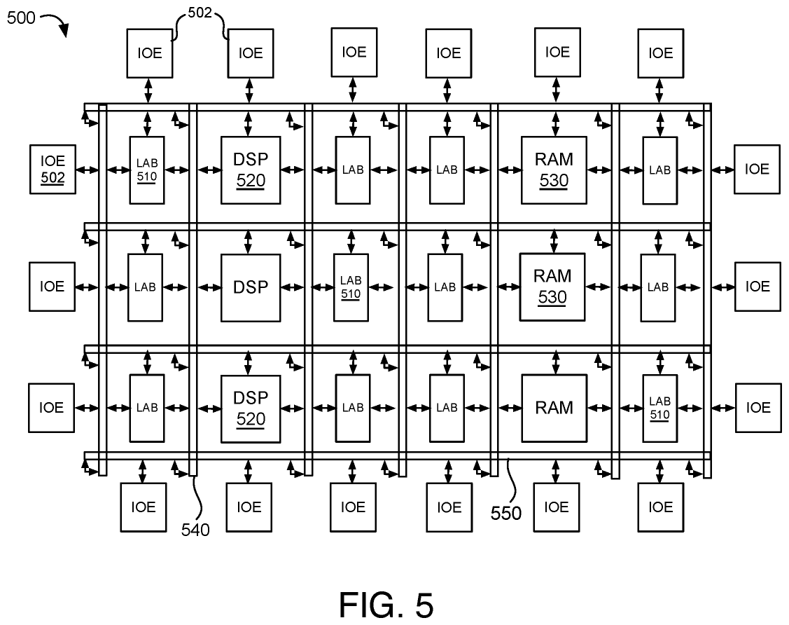

FIG. 4 is a diagram that illustrates a portion of another integrated circuit 400 that includes several configurable logic circuit blocks. Integrated circuit (IC) 400 can be any type of integrated circuit (IC), such as, a configurable (i.e., programmable) logic IC, a microprocessor IC, or a graphics processing unit (GPU) IC. IC 400 includes configurable logic circuit blocks arranged in horizontal rows and vertical columns. Each of the configurable logic circuit blocks in IC 400 is depicted as a rectangle in FIG. 4.

In the example of FIG. 4, the configurable logic circuit blocks are arranged in 4-column logic array blocks (LAB4s), such as LAB4s 421-424. FIG. 4 shows three columns of the LAB4s. LAB4s 421-424 are arranged in a first one of the 3 columns. Each of the LAB4s in the example of FIG. 4 includes 40 configurable logic circuit blocks arranged in 4 columns and 10 rows. As an example, LAB4 421 has 40 configurable logic circuit blocks, including configurable logic circuit blocks 441 and 442. IC 400 also includes data register circuitry 401 that has at least three multiplexer circuits 411-413. Each of the multiplexer circuits 411-413 is coupled to a bus 415 and to one of the 3 columns of LAB4s.

In the example of FIG. 4, each of the configurable logic circuit blocks in the LAB4s includes the circuits and conductors (wires) of configurable logic circuit block 100 as disclosed herein with respect to FIG. 1. Thus, each of the configurable logic circuit blocks of FIG. 4 includes an instance of the configurable logic circuit block 100 of FIG. 1. The configurable logic circuit block 441 of FIG. 4 is configured as described above with respect to FIGS. 1 and 2A-2C. Thus, the adaptive logic module 101 in configurable logic circuit block 441 functions as a trace register during a non-destructive readback operation from a synchronous circuit in a circuit design operating as a DUT during an emulation mode.

During the non-destructive readback operation, a series of the states of a readback signal from the synchronous circuit in the circuit design for the DUT are sequentially stored in the adaptive logic module 101 in configurable logic circuit block 441. The configurable logic circuit blocks in the LAB4s shown in FIG. 4 are configured to form a scan chain as shown by the dotted paths 430-432 to sequentially store the states of the readback signal as received from the configurable logic circuit block 441. The configurable logic circuit blocks in the scan chain are coupled together through conductors and multiplexers along paths 430-432.

Each state of the readback signal is stored in configurable logic circuit block 441 and then sequentially shifted through the adaptive logic modules 102 and 104 in the configurable logic circuit blocks in the first column of the LAB4s through path 430. Each state of the readback signal is then provided from path 430 through conductor 425 and multiplexer circuit 412 to the second column of LAB4s. Each state of the readback signal is then sequentially shifted through the configurable logic circuit blocks in the second column of LAB4s through path 431. Each state of the readback signal is then provided from path 431 through conductor 426 and multiplexer circuit 413 to the third column of LAB4s. Each state of the readback signal is then sequentially shifted through the configurable logic circuit blocks in the third column of LAB4s through path 432 and additional columns of LAB4s to user emulation soft logic circuitry 460. Using this configuration, serially received states of the readback signal are scanned through the scan chain formed by the adaptive logic modules 102 and 104 in the configurable logic circuit blocks in the columns of the LAB4s, as shown for example by dotted paths 430-432, to user emulation soft logic circuitry 460 (e.g., configurable logic circuitry in a fabric region of a configurable logic IC).

FIG. 5 illustrates an example of a configurable logic integrated circuit (IC) 500 that can include, for example, the circuitry disclosed herein with respect to any, some, or all of FIGS. 1, 2A-2C, 3, and 4. As shown in FIG. 5, the programmable logic integrated circuit (IC) 500 includes a two-dimensional array of configurable functional circuit blocks, including configurable logic array blocks (LABs) 510 and other functional circuit blocks, such as random access memory (RAM) blocks 530 and digital signal processing (DSP) blocks 520. Functional blocks such as LABs 510 can include smaller programmable logic circuits (e.g., logic elements, logic blocks, or adaptive logic modules) that receive input signals and perform custom functions on the input signals to produce output signals. The configurable functional circuit blocks shown in FIG. 5 can, for example, be configured to perform the functions of any of the circuitry disclosed herein with respect to FIGS. 1, 2A-2C, 3, and 4.

In addition, programmable logic IC 500 can have input/output elements (IOEs) 502 for driving signals off of programmable logic IC 500 and for receiving signals from other devices. Input/output elements 502 can include parallel input/output circuitry, serial data transceiver circuitry, differential receiver and transmitter circuitry, or other circuitry used to connect one integrated circuit to another integrated circuit. As shown, input/output elements 502 can be located around the periphery of the chip. If desired, the programmable logic IC 500 can have input/output elements 502 arranged in different ways. For example, input/output elements 502 can form one or more columns, rows, or islands of input/output elements that may be located anywhere on the programmable logic IC 500.

The programmable logic IC 500 can also include programmable interconnect circuitry in the form of vertical routing channels 540 (i.e., interconnects formed along a vertical axis of programmable logic IC 500) and horizontal routing channels 550 (i.e., interconnects formed along a horizontal axis of programmable logic IC 500), each routing channel including at least one conductor to route at least one signal.

Note that other routing topologies, besides the topology of the interconnect circuitry depicted in FIG. 5, may be used. For example, the routing topology can include wires that travel diagonally or that travel horizontally and vertically along different parts of their extent as well as wires that are perpendicular to the device plane in the case of three dimensional integrated circuits. The driver of a wire can be located at a different point than one end of a wire.

Furthermore, it should be understood that embodiments disclosed herein with respect to FIGS. 1, 2A-2C, 3, and 4 can be implemented in any integrated circuit or electronic system. If desired, the functional blocks of such an integrated circuit can be arranged in more levels or layers in which multiple functional blocks are interconnected to form still larger blocks. Other device arrangements can use functional blocks that are not arranged in rows and columns.

Programmable logic IC 500 can contain programmable memory elements. Memory elements can be loaded with configuration data using input/output elements (IOEs) 502. Once loaded, the memory elements each provide a corresponding static control signal that controls the operation of an associated configurable functional block (e.g., LABs 510, DSP blocks 520, RAM blocks 530, or input/output elements 502).

In a typical scenario, the outputs of the loaded memory elements are applied to the gates of metal-oxide-semiconductor field-effect transistors (MOSFETs) in a functional block to turn certain transistors on or off and thereby configure the logic in the functional block including the routing paths. Programmable logic circuit elements that can be controlled in this way include multiplexers (e.g., multiplexers used for forming routing paths in interconnect circuits), look-up tables, logic arrays, AND, OR, XOR, NAND, and NOR logic gates, pass gates, etc.

The programmable memory elements can be organized in a configuration memory array having rows and columns. A data register that spans across all columns and an address register that spans across all rows can receive configuration data. The configuration data can be shifted onto the data register. When the appropriate address register is asserted, the data register writes the configuration data to the configuration memory bits of the row that was designated by the address register.

In certain embodiments, programmable logic IC 500 can include configuration memory that is organized in sectors, whereby a sector can include the configuration RAM bits that specify the functions and/or interconnections of the subcomponents and wires in or crossing that sector. Each sector can include separate data and address registers.

The programmable logic IC of FIG. 5 is merely one example of an IC that can be used with embodiments disclosed herein. The embodiments disclosed herein can be used with any suitable integrated circuit or system. For example, the embodiments disclosed herein can be used with numerous types of devices such as processor integrated circuits, central processing units, memory integrated circuits, graphics processing unit integrated circuits, application specific standard products (ASSPs), application specific integrated circuits (ASICs), and programmable logic integrated circuits. Examples of programmable logic integrated circuits include programmable arrays logic (PALs), programmable logic arrays (PLAs), field programmable logic arrays (FPGAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

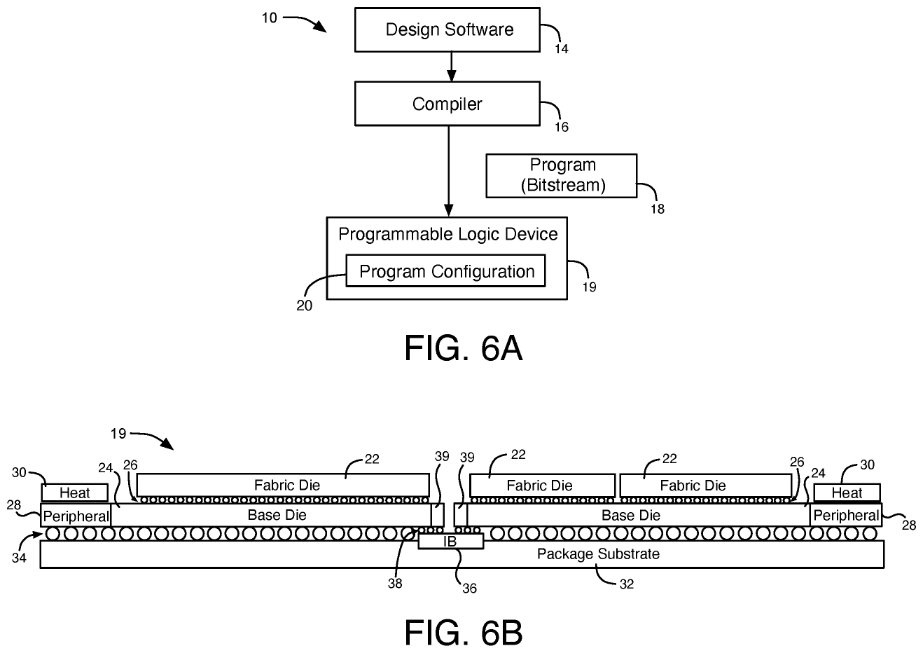

FIG. 6A illustrates a block diagram of a system 10 that can be used to implement a circuit design to be programmed into a programmable logic device 19 using design software. A designer can implement circuit design functionality on an integrated circuit, such as a reconfigurable programmable logic device 19 (e.g., a field programmable gate array (FPGA)). The designer can implement the circuit design to be programmed onto the programmable logic device 19 using design software 14. The design software 14 can use a compiler 16 to generate a low-level circuit-design program (bitstream) 18, sometimes known as a program object file and/or configuration program, that programs the programmable logic device 19. Thus, the compiler 16 can provide machine-readable instructions representative of the circuit design to the programmable logic device 19. For example, the programmable logic device 19 can receive one or more programs (bitstreams) 18 that describe the hardware implementations that should be stored in the programmable logic device 19. A program (bitstream) 18 can be programmed into the programmable logic device 19 as a configuration program 20. The configuration program 20 can, in some cases, represent an accelerator function to perform for machine learning, video processing, voice recognition, image recognition, or other highly specialized task.

In some implementations, a programmable logic device can be any integrated circuit device that includes a programmable logic device with two separate integrated circuit die where at least some of the programmable logic fabric is separated from at least some of the fabric support circuitry that operates the programmable logic fabric. One example of such a programmable logic device is shown in FIG. 6B, but many others can be used, and it should be understood that this disclosure is intended to encompass any suitable programmable logic device where programmable logic fabric and fabric support circuitry are at least partially separated on different integrated circuit die.

FIG. 6B is a diagram that depicts an example of the programmable logic device 19 that includes three fabric die 22 and two base die 24 that are connected to one another via microbumps 26. In the example of FIG. 6B, at least some of the programmable logic fabric of the programmable logic device 19 is in the three fabric die 22, and at least some of the fabric support circuitry that operates the programmable logic fabric is in the two base die 24. For example, some of the circuitry of configurable IC 500 shown in FIG. 5 (e.g., LABs 510, DSP 520, and RAM 530) can be located in the fabric die 22 and some of the circuitry of IC 500 (e.g., input/output elements 502) can be located in the base die 24.

Although the fabric die 22 and base die 24 appear in a one-to-one relationship or a two-to-one relationship in FIG. 6B, other relationships can be used. For example, a single base die 24 can attach to several fabric die 22, or several base die 24 can attach to a single fabric die 22, or several base die 24 can attach to several fabric die 22 (e.g., in an interleaved pattern). Peripheral circuitry 28 can be attached to, embedded within, and/or disposed on top of the base die 24, and heat spreaders 30 can be used to reduce an accumulation of heat on the programmable logic device 19. The heat spreaders 30 can appear above, as pictured, and/or below the package (e.g., as a double-sided heat sink). The base die 24 can attach to a package substrate 32 via conductive bumps 34. In the example of FIG. 6B, two pairs of fabric die 22 and base die 24 are shown communicatively connected to one another via an interconnect bridge 36 (e.g., an embedded multi-die interconnect bridge (EMIB)) and microbumps 38 at bridge interfaces 39 in base die 24.

In combination, the fabric die 22 and the base die 24 can operate in combination as a programmable logic device 19 such as a field programmable gate array (FPGA). It should be understood that an FPGA can, for example, represent the type of circuitry, and/or a logical arrangement, of a programmable logic device when both the fabric die 22 and the base die 24 operate in combination. Moreover, an FPGA is discussed herein for the purposes of this example, though it should be understood that any suitable type of programmable logic device can be used.

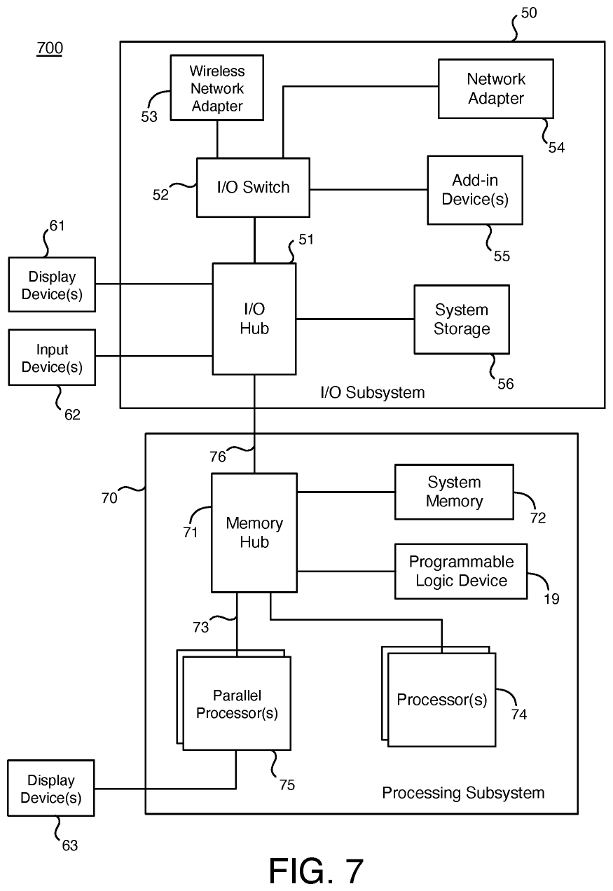

FIG. 7 is a block diagram illustrating a computing system 700 configured to implement one or more aspects of the embodiments described herein. The computing system 700 includes a processing subsystem 70 having one or more processor(s) 74, a system memory 72, and a programmable logic device 19 communicating via an interconnection path that can include a memory hub 71. The memory hub 71 can be a separate component within a chipset component or can be integrated within the one or more processor(s) 74. The memory hub 71 couples with an input/output (I/O) subsystem 50 via a communication link 76. The I/O subsystem 50 includes an input/output (I/O) hub 51 that can enable the computing system 700 to receive input from one or more input device(s) 62. Additionally, the I/O hub 51 can enable a display controller, which can be included in the one or more processor(s) 74, to provide outputs to one or more display device(s) 61. In one embodiment, the one or more display device(s) 61 coupled with the I/O hub 51 can include a local, internal, or embedded display device.

In one embodiment, the processing subsystem 70 includes one or more parallel processor(s) 75 coupled to memory hub 71 via a bus or other communication link 73. The communication link 73 can use one of any number of standards based communication link technologies or protocols, such as, but not limited to, PCI Express, or can be a vendor specific communications interface or communications fabric. In one embodiment, the one or more parallel processor(s) 75 form a computationally focused parallel or vector processing system that can include a large number of processing cores and/or processing clusters, such as a many integrated core (MIC) processor. In one embodiment, the one or more parallel processor(s) 75 form a graphics processing subsystem that can output pixels to one of the one or more display device(s) 61 coupled via the I/O Hub 51. The one or more parallel processor(s) 75 can also include a display controller and display interface (not shown) to enable a direct connection to one or more display device(s) 63.

Within the I/O subsystem 50, a system storage unit 56 can connect to the I/O hub 51 to provide a storage mechanism for the computing system 700. An I/O switch 52 can be used to provide an interface mechanism to enable connections between the I/O hub 51 and other components, such as a network adapter 54 and/or a wireless network adapter 53 that can be integrated into the platform, and various other devices that can be added via one or more add-in device(s) 55. The network adapter 54 can be an Ethernet adapter or another wired network adapter. The wireless network adapter 53 can include one or more of a Wi-Fi, Bluetooth, near field communication (NFC), or other network device that includes one or more wireless radios.

The computing system 700 can include other components not shown in FIG. 7, including other port connections, optical storage drives, video capture devices, and the like, that can also be connected to the I/O hub 51. Communication paths interconnecting the various components in FIG. 7 can be implemented using any suitable protocols, such as PCI (Peripheral Component Interconnect) based protocols (e.g., PCI-Express), or any other bus or point-to-point communication interfaces and/or protocol(s), such as the NV-Link high-speed interconnect, or interconnect protocols known in the art.

In one embodiment, the one or more parallel processor(s) 75 incorporate circuitry optimized for graphics and video processing, including, for example, video output circuitry, and constitutes a graphics processing unit (GPU). In another embodiment, the one or more parallel processor(s) 75 incorporate circuitry optimized for general purpose processing, while preserving the underlying computational architecture. In yet another embodiment, components of the computing system 700 can be integrated with one or more other system elements on a single integrated circuit. For example, the one or more parallel processor(s) 75, memory hub 71, processor(s) 74, and I/O hub 51 can be integrated into a system on chip (SoC) integrated circuit. Alternatively, the components of the computing system 700 can be integrated into a single package to form a system in package (SIP) configuration. In one embodiment, at least a portion of the components of the computing system 700 can be integrated into a multi-chip module (MCM), which can be interconnected with other multi-chip modules into a modular computing system.

The computing system 700 shown herein is illustrative. Other variations and modifications are also possible. The connection topology, including the number and arrangement of bridges, the number of processor(s) 74, and the number of parallel processor(s) 75, can be modified as desired. For instance, in some embodiments, system memory 72 is connected to the processor(s) 74 directly rather than through a bridge, while other devices communicate with system memory 72 via the memory hub 71 and the processor(s) 74. In other alternative topologies, the parallel processor(s) 75 are connected to the I/O hub 51 or directly to one of the one or more processor(s) 74, rather than to the memory hub 71. In other embodiments, the I/O hub 51 and memory hub 71 can be integrated into a single chip. Some embodiments can include two or more sets of processor(s) 74 attached via multiple sockets, which can couple with two or more instances of the parallel processor(s) 75.

Some of the particular components shown herein are optional and may not be included in all implementations of the computing system 700. For example, any number of add-in cards or peripherals can be supported, or some components can be eliminated. Furthermore, some architectures can use different terminology for components similar to those illustrated in FIG. 7. For example, the memory hub 71 can be referred to as a Northbridge in some architectures, while the I/O hub 51 can be referred to as a Southbridge.

Additional examples are now described. Example 1 is an integrated circuit comprising: a first logic circuit block comprising a first adaptive logic module that is configurable to store a first state of a first signal received from a device-under-test in a first register, a second adaptive logic module that is configurable to store a second state of a second signal in a second register during a user mode of the integrated circuit simultaneously with the first state of the first signal being stored in the first register, and a third adaptive logic module that is configurable to store a third state of the first signal in a third register, wherein the first and the third states of the first signal are stored for consecutive clock cycles in the first register and the third register, and wherein the first logic circuit block is configurable to scan out the second state in the second register and the third state in the third register.

In Example 2, the integrated circuit of Example 1 can optionally include, wherein each of the first and the second adaptive logic modules comprises a lookup table.

In Example 3, the integrated circuit of any one of Examples 1-2 can optionally include, wherein the first logic circuit block further comprises a dedicated design-for-test output scan path.

In Example 4, the integrated circuit of any one of Examples 1-3 can optionally include, wherein the first logic circuit block further comprises a fourth adaptive logic module that is configurable to store a fourth state of the first signal in a fourth register.

In Example 5, the integrated circuit of Example 4 can optionally include, wherein the third and the fourth states of the first signal are stored for consecutive clock cycles in the third register and the fourth register.

In Example 6, the integrated circuit of Example 4 can optionally include, wherein the first logic circuit block is configurable to scan out the fourth state in the fourth register.

In Example 7, the integrated circuit of any one of Examples 1-6 further comprises: a second logic circuit block comprising a fourth adaptive logic module that is configurable to store a fourth state of the first signal received from the first logic circuit block in a fourth register, and a fifth adaptive logic module that is configurable to store a fifth state of the first signal in a fifth register, wherein the fourth and the fifth states of the first signal are stored for consecutive clock cycles in the fourth register and the fifth register.

In Example 8, the integrated circuit of Example 7 can optionally include, wherein the second logic circuit block further comprises a sixth adaptive logic module that is configurable to store a sixth state of a third signal in a sixth register during the user mode simultaneously with the fourth state of the first signal being stored in the fourth register.

In Example 9, the integrated circuit of Example 7 can optionally include, wherein the second logic circuit block further comprises a sixth adaptive logic module that is configurable to store a sixth state of the first signal in a sixth register.

Example 10 is a method for accessing a first signal from a design-under-test in an integrated circuit, the method comprising: storing a first state of the first signal received from the device-under-test in a first register in a first adaptive logic module in a logic circuit block in the integrated circuit; storing a second state of a second signal in a second register in a second adaptive logic module in the logic circuit block simultaneously with the first state of the first signal being stored in the first register during a user mode of the integrated circuit; storing a third state of the first signal in a third register in a third adaptive logic module in the logic circuit block, wherein the first and the third states of the first signal are stored for consecutive clock cycles in the first register and the third register; and scanning out the second state of the second signal in the second register and the third state of the first signal in the third register.

In Example 11, the method of Example 10 can optionally include, wherein each of the first, the second, and the third adaptive logic modules comprises a lookup table.

In Example 12, the method of any one of Examples 10-11 further comprises: storing a fourth state of the first signal in a fourth register in a fourth adaptive logic module in the logic circuit block.

In Example 13, the method of Example 12 can optionally include, wherein the third and the fourth states of the first signal are stored for consecutive clock cycles in the third register and the fourth register.

In Example 14, the method of Example 12 further comprises: scanning out the fourth state of the first signal in the fourth register.

In Example 15, the method of any one of Examples 10-14, wherein the integrated circuit is a configurable logic integrated circuit.

Example 16 is a configurable integrated circuit comprising: a logic block comprising a first configurable logic circuit that is coupled to store a first state of a first signal received from a device-under-test in a first latch, a second configurable logic circuit that is coupled to store a second state of a second signal in a second latch during a user mode of the configurable integrated circuit simultaneously with the first state of the first signal being stored in the first latch, and a third configurable logic circuit that is coupled to store a third state of the first signal in a third latch, wherein the first and the third states of the first signal are stored for consecutive cycles of a clock signal in the first latch and the third latch, and wherein the logic block is configurable to scan out the second state of the second signal in the second latch and the third state of the first signal in the third latch.

In Example 17, the configurable integrated circuit of Example 16 can optionally include, wherein each of the first, the second, and the third configurable logic circuits comprises a lookup table.

In Example 18, the configurable integrated circuit of any one of Examples 16-17 can optionally include, wherein the logic block further comprises a dedicated design-for-test output scan path.

In Example 19, the configurable integrated circuit of any one of Examples 16-18 can optionally include, wherein the logic block further comprises a fourth configurable logic circuit that is coupled to store a fourth state of the first signal in a fourth latch.

In Example 20, the configurable integrated circuit of Example 19 can optionally include, wherein the third and the fourth states of the first signal are stored for consecutive clock cycles in the third latch and the fourth latch.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

What is claimed is:

1. An integrated circuit comprising:
a first logic circuit block comprising a first adaptive logic module that is configurable to store a first state of a first signal received from a device-under-test in a first register, a second adaptive logic module that is configurable to store a second state of a second signal in a second register during a user mode of the integrated circuit simultaneously with the first state of the first signal being stored in the first register, and a third adaptive logic module that is configurable to store a third state of the first signal in a third register, wherein the first and the third states of the first signal are stored for consecutive clock cycles in the first register and the third register, and wherein the first logic circuit block is configurable to scan out the second state in the second register and the third state in the third register.

2. The integrated circuit of claim 1, wherein each of the first and the second adaptive logic modules comprises a lookup table.

3. The integrated circuit of claim 1, wherein the first logic circuit block further comprises a dedicated design-for-test output scan path.

4. The integrated circuit of claim 1, wherein the first logic circuit block further comprises a fourth adaptive logic module that is configurable to store a fourth state of the first signal in a fourth register.

5. The integrated circuit of claim 4, wherein the third and the fourth states of the first signal are stored for consecutive clock cycles in the third register and the fourth register.

6. The integrated circuit of claim 4, wherein the first logic circuit block is configurable to scan out the fourth state in the fourth register.

7. The integrated circuit of claim 1 further comprising:
a second logic circuit block comprising a fourth adaptive logic module that is configurable to store a fourth state of the first signal received from the first logic circuit block in a fourth register, and a fifth adaptive logic module that is configurable to store a fifth state of the first signal in a fifth register, wherein the fourth and the fifth states of the first signal are stored for consecutive clock cycles in the fourth register and the fifth register.

8. The integrated circuit of claim 7, wherein the second logic circuit block further comprises a sixth adaptive logic module that is configurable to store a sixth state of a third signal in a sixth register during the user mode simultaneously with the fourth state of the first signal being stored in the fourth register.

9. The integrated circuit of claim 7, wherein the second logic circuit block further comprises a sixth adaptive logic module that is configurable to store a sixth state of the first signal in a sixth register.

10. A method for accessing a first signal from a design-under-test in an integrated circuit, the method comprising:
storing a first state of the first signal received from the device-under-test in a first register in a first adaptive logic module in a logic circuit block in the integrated circuit;
storing a second state of a second signal in a second register in a second adaptive logic module in the logic circuit block simultaneously with the first state of the first signal being stored in the first register during a user mode of the integrated circuit;
storing a third state of the first signal in a third register in a third adaptive logic module in the logic circuit block, wherein the first and the third states of the first signal are stored for consecutive clock cycles in the first register and the third register; and
scanning out the second state of the second signal in the second register and the third state of the first signal in the third register.

11. The method of claim 10, wherein each of the first, the second, and the third adaptive logic modules comprises a lookup table.

12. The method of claim 10 further comprising:
storing a fourth state of the first signal in a fourth register in a fourth adaptive logic module in the logic circuit block.

13. The method of claim 12, wherein the third and the fourth states of the first signal are stored for consecutive clock cycles in the third register and the fourth register.

14. The method of claim 12 further comprising:
scanning out the fourth state of the first signal in the fourth register.

15. The method of claim 10, wherein the integrated circuit is a configurable logic integrated circuit.

16. A configurable integrated circuit comprising:
a logic block comprising a first configurable logic circuit that is coupled to store a first state of a first signal received from a device-under-test in a first latch, a second configurable logic circuit that is coupled to store a second state of a second signal in a second latch during a user mode of the configurable integrated circuit simultaneously with the first state of the first signal being stored in the first latch, and a third configurable logic circuit that is coupled to store a third state of the first signal in a third latch, wherein the first and the third states of the first signal are stored for consecutive cycles of a clock signal in the first latch and the third latch, and wherein the logic block is configurable to scan out the second state of the second signal in the second latch and the third state of the first signal in the third latch.

17. The configurable integrated circuit of claim 16, wherein each of the first, the second, and the third configurable logic circuits comprises a lookup table.

18. The configurable integrated circuit of claim 16, wherein the logic block further comprises a dedicated design-for-test output scan path.

19. The configurable integrated circuit of claim 16, wherein the logic block further comprises a fourth configurable logic circuit that is coupled to store a fourth state of the first signal in a fourth latch.

20. The configurable integrated circuit of claim 19, wherein the third and the fourth states of the first signal are stored for consecutive clock cycles in the third latch and the fourth latch.
